(19) United States
(12) Patent Application Publication
(10) Pub. No.: US 2021/0082926 A1
(43) Pub. Date: Mar. 18, 2021

(54) SEMICONDUCTOR DEVICE

(71) Applicant: Kioxia Corporation, Minato-ku (JP)

(72) Inventors: Takayuki KAKEGAWA, Yokkaichi (JP); Shinya Naito, Toyota (JP)

(73) Assignee: Kioxia Corporation, Minato-ku (JP)

(21) Appl. No.: 16/813,060

(22) Filed: Mar. 9, 2020

(30) Foreign Application Priority Data
Sep. 17, 2019 (JP) 2019-168747

(51) Int. Cl. H01L 27/1157; H01L 27/11524; H01L 27/11556; H01L 27/11582; H01L 29/10; H01L 21/74; H01L 21/265; H01L 21/324

(52) U.S. Cl. CPC H01L 27/1157; H01L 27/11524; H01L 27/11556; H01L 21/324; H01L 29/1083; H01L 21/74; H01L 21/2652; H01L 27/11582

(57) ABSTRACT

According to an embodiment, a semiconductor device has a first and second region, and a semiconductor channel. The first region includes a peak of a concentration profile of a first impurity of a first conductivity type. The first region extends from a surface of the substrate, through a depth range including the concentration profile of a second impurity of a second conductivity type, to a depth of an intersection of the concentration profile of the first impurity and the concentration profile of the second impurity. The second region includes a concentration profile of a third impurity, and the second region overlaps at least part of the first region. The concentration profile of the third impurity is higher in concentration than the concentration profile of the first impurity throughout a depth direction of the second region. One end of the semiconductor channel reaches the first and second region.

### CROSS-REFERENCE TO RELATED APPLICATIONS

This application is based upon and claims the benefit of priority from Japanese Patent Application No. 2019-168747, filed on Sep. 17, 2019; the entire contents of which are incorporated herein by reference.

### FIELD

Embodiments described herein relate generally to a semiconductor device.

### BACKGROUND

In a semiconductor device having a three-dimensional structure, a stacked body in which a conductive film and an insulating film are alternately layered on a substrate is penetrated by a columnar semiconductor, and thus a three-dimensional transistor arrangement can be configured in a place where the conductive film and the semiconductor intersect. At this time, it is desirable that the threshold value of the transistor should be appropriate.

### BRIEF DESCRIPTION OF THE DRAWINGS

FIG. 1 is a perspective view illustrating a configuration of a semiconductor device according to an embodiment;

FIG. 2 is a circuit diagram illustrating a configuration of a memory cell array in the embodiment;

FIG. 3 is a plan view illustrating the configuration of the memory cell array in the embodiment;

FIG. 4 is a cross-sectional view illustrating the configuration of the memory cell array in the embodiment;

FIG. 5 is a cross-sectional view illustrating a semiconductor region near a source-side selection transistor in the embodiment;

FIG. 6 is a diagram illustrating impurity concentration profiles of a semiconductor region of a first conductivity type and a semiconductor region of a second conductivity type in the embodiment;

FIG. 7 is a diagram illustrating an impurity concentration profile of a diffusion inhibiting region in the embodiment;

FIG. 8A and FIG. 8B are process cross-sectional views illustrating a manufacturing method for a semiconductor device according to the embodiment;

FIG. 9 is a diagram illustrating the voltage-current characteristics of the source-side selection transistor in the embodiment;

FIG. 10 is a cross-sectional view illustrating a semiconductor region near a source-side selection transistor in a first modified example of the embodiment;

FIG. 11 is a diagram illustrating an impurity concentration profile of a diffusion inhibiting region in the first modified example of the embodiment;

FIG. 12 is a cross-sectional view illustrating a semiconductor region near a source-side selection transistor in a second modified example of the embodiment;

FIG. 13 is a diagram illustrating an impurity concentration profile of a diffusion inhibiting region in the second modified example of the embodiment; and

FIG. 14 is a cross-sectional view illustrating a semiconductor region near a source-side selection transistor in a third modified example of the embodiment.

### DETAILED DESCRIPTION

According to the present embodiment, a semiconductor device having a stacked body, a first region, a second region, and a semiconductor channel is provided. The stacked body is disposed above a substrate. In the stacked body, a plurality of conductive films are interspatially arranged in a layering direction. The first region is disposed in the substrate. The first region includes a peak of a concentration profile of a first impurity of a first conductivity type. The first region extends from a surface of the substrate, through a depth range including a concentration profile of a second impurity of a second conductivity type higher in concentration than the concentration profile of the first impurity having the peak, to a depth of an intersection of the concentration profile of the first impurity having the peak and the concentration profile of the second impurity. The second region is disposed in the substrate. The second region includes a concentration profile of a third impurity, and the second region overlaps at least part of the first region in the layering direction. The concentration profile of the third impurity is higher in concentration than the concentration profile of the first impurity throughout a depth direction of the second region. The semiconductor channel penetrates the stacked body in the layering direction. One end of the semiconductor channel reaches the first region and the second region.

Referring to the accompanying drawings, a semiconductor device according to an embodiment will be described in detail below. Note that the present invention is not limited by this embodiment.

### Embodiment

In a semiconductor device, a stacked body in which a conductive film and an insulating film are alternately layered may be penetrated by columnar semiconductor channels to form a three-dimensional memory cell arrangement (a memory cell array). In this semiconductor device, the storage capacity can be increased by increasing the number of films and, therefore, the need to use a more advanced patterning technique can be reduced, making it possible to easily reduce the cost per bit.

Where the semiconductor device is a three-dimensional semiconductor memory, a portion where a conductive film and a semiconductor channel intersect is configured to function as a memory cell, and a memory cell array in which a plurality of memory cells are three-dimensionally arranged is configured. A portion, intersecting a semiconductor channel, of a conductive film functions as a control gate in a memory cell, and the remaining portion of the conductive film can function as a word line transmitting a signal to the control gate.

The memory cell array includes a plurality of memory strings in which a plurality of memory cells are connected in series in a string. A portion of the lowermost conductive film in the stacked body which intersects the semiconductor channel functions as a gate in a source-side selection transistor for selecting a memory string, and the remaining portion of the lowermost conductive film can function as a selection gate line (SGS). A substrate is disposed below the lowermost conductive film, and the lower end side portion of the semiconductor channel reaches a semiconductor region in the substrate.

This semiconductor region can be formed by implanting an impurity of the first conductivity type in the substrate and near the surface thereof in a well formation step for adjusting the threshold voltage Vth of the source-side selection transistor. The first conductivity type is, for example, P-type, and an impurity of the first conductivity type is, for example, boron. That is, this semiconductor region is located in the substrate and near the surface thereof and contains the impurity of the first conductivity type.

However, the impurity of this first conductivity type tends to diffuse in the substrate in the depth direction in a subsequent step, and the concentration near the substrate surface tends to decrease. As a result, the threshold voltage Vth of the source-side selection transistor decreases, making it difficult to satisfy desired cutoff characteristics.

If ion implantation at a high dose of an impurity of the first conductivity type is performed in order to inhibit a decrease in the threshold voltage Vth of the source-side selection transistor, the manufacturing cost of the semiconductor device may increase. In addition, the impurity of the first conductivity type may have a high concentration in a slightly deep region of the substrate due to diffusion and may overlap with a high concentration portion of a source line diffusion layer. The source line diffusion layer is a semiconductor region containing an impurity of a second conductivity type. The second conductivity type is a conductivity type opposite to the first conductivity type. For example, if the first conductivity type is P-type, the second conductivity type is N-type, and the impurity of the second conductivity type is, for example, arsenic. In this case, there is a possibility that a junction leak may occur between the semiconductor region of the first conductivity type and the semiconductor region of the second conductivity type (source line diffusion layer).

Therefore, in the present embodiment, in the semiconductor device, an impurity (for example, carbon) region that inhibits diffusion of the impurity of the first conductivity type is formed in the semiconductor region of the first conductivity type, thereby inhibiting diffusion of the impurity of the first conductivity type in the substrate and optimizing the threshold voltage of the source-side selection transistor.

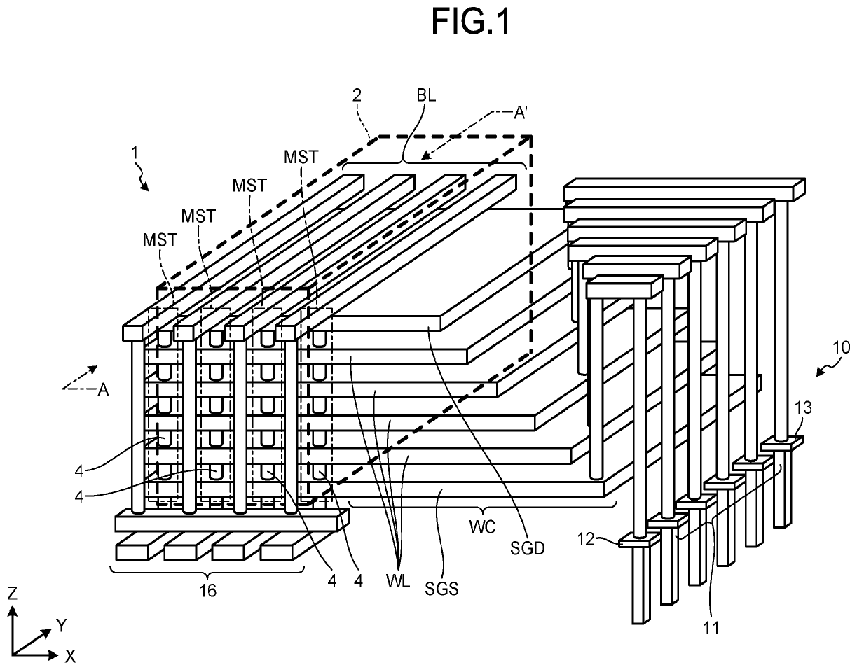

Specifically, the semiconductor device 1 is configured as illustrated in FIG. 1. FIG. 1 is a perspective view illustrating a configuration of the semiconductor device 1.

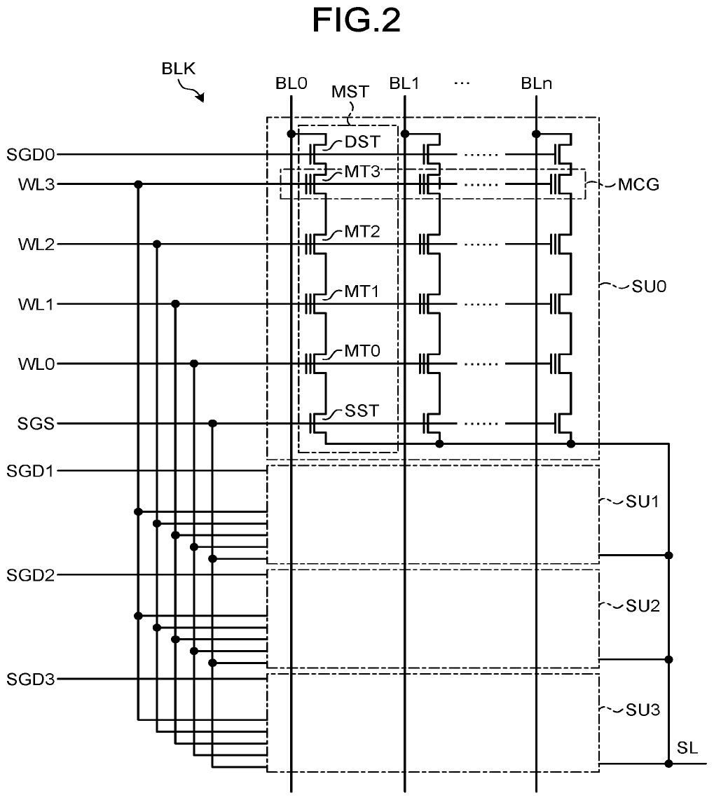

The semiconductor device 1 is a three-dimensional semiconductor memory, for example, a NAND flash memory. The semiconductor device 1 has a memory cell array 2, a control circuit 10, a word line WL, a selection gate line SGS, a selection gate line SGD, a bit line BL, and a source line SL (see FIG. 2). The control circuit 10 includes a WL control circuit 11, an SGS control circuit 12, an SGD control circuit 13, and a sense amplifier circuit 16. Hereinafter, the extending direction of the bit line BL is called a Y direction, the stacking direction of the memory cell transistors is called a Z direction, and a direction perpendicular to the Y direction and the Z direction is called an X direction.

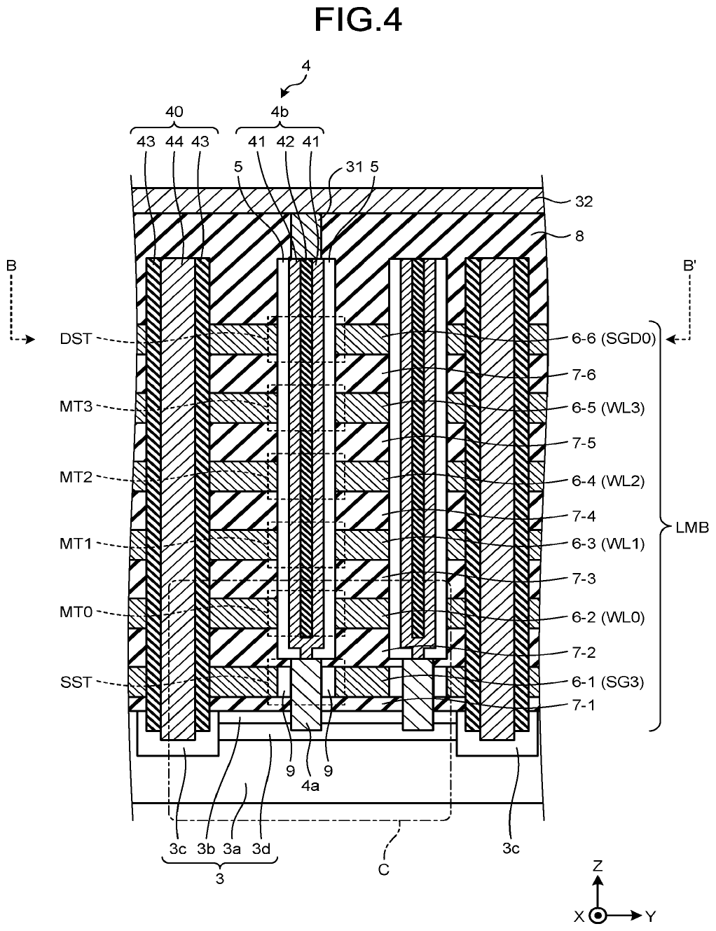

The memory cell array 2 illustrated in FIG. 1 has a configuration in which a plurality of memory strings MST are arranged on a substrate 3 (see FIG. 4), each memory string MST including: a memory cell string in which one or more memory cell transistors (hereinafter, also simply referred to as memory cell/cells) are arranged in the Z direction; and a drain-side selection transistor DST and a source-side selection transistor SST (see FIG. 2) provided at the upper end and the lower end, respectively, of the memory cell string. A plurality of memory cells MT0 to MT3 and selection transistors DST, SST are configured in positions where conductive films (SGS, WL, SGD) and columnar bodies 4 intersect in the structure in which the columnar bodies 4 penetrate an stacked body LMB (see FIG. 4) in which a conductive film (SGS, WL, SGD) and an insulating film are repeatedly arranged in the Z direction. In each of the memory cells MT0 to MT3, a portion, intersecting the columnar body 4, of a plate-shaped conductive film (a word line WL) functions as a control gate. In the drain-side selection transistor DST, a portion, intersecting the columnar body 4, of the plate-shaped conductive film (the selection gate line SGD) functions as a control gate. In the source-side selection transistor SST, a portion, intersecting the columnar body 4, of the plate-shaped conductive film (the selection gate line SGS) functions as a control gate. Here, an example shows a case where four layers of memory cells are provided in one memory string MST.

Each of the word lines WL connects the control gates of the memory cells of the same height in the memory strings MST present in a predetermined range. The selection gate line SGS connects the control gates of the source-side selection transistors SST of the memory strings MST present in the predetermined range, and the selection gate line SGD connects the control gates of the drain-side selection transistors DST of the memory strings MST present in the predetermined range. A bit line BL extends in the Y direction and is connected to the upper portion of each memory string MST.

Each of the WL control circuits 11 is a circuit that controls a voltage applied to the respective word line WL, the SGS control circuit 12 is a circuit that controls a voltage applied to the selection gate line SGS, and the SGD control circuit 13 is a circuit that controls a voltage applied to the selection gate line SGD. Each of the sense amplifier circuits 16 is a circuit that, according to a signal read from a selected memory cell, detects the threshold voltage of the memory cell.

The word lines WL, selection gate lines SGS and SGD of the memory cell array 2 and the WL control circuits 11, SGS control circuit 12 and SGD control circuit 13 are connected by means of a word line contact portion WC (electrode line contact portion) provided in the memory cell array 2 via contacts. The word line contact portion WC is provided on the WL control circuit 11 side of the memory cell array 2, and has a structure in which the word lines WL connected to the memory cells MT0 to MT3 of respective heights and the selection gate lines SGS, SGD connected to the selection transistors DST and SST are processed to have a staircase form.

The control circuit 10 controls an operation of the semiconductor device 1, based on an instruction input from outside (for example, a memory controller) via the interface. For example, when receiving a writing instruction, the control circuit 10 writes, in a memory cell of a specified address in the memory cell array 2, data specified for writing. Further, when receiving a reading instruction, the control circuit 10 reads data from the memory cell of the specified address in the memory cell array 2 and outputs the data to outside (the memory controller) via the interface.

Next, a circuit configuration of the memory cell array 2 will be described with reference to FIG. 2. FIG. 2 is a diagram illustrating a circuit configuration of the memory cell array 2, and exemplifies one block BLK among a plurality of blocks BLK included in the memory cell array 2.

In FIG. 2, in the block BLK, for example, four word lines WL0 to WL3, selection gate lines SGD0 to SGD3, SGS, and a source line SL are provided. Each word line WL and selection gate line SGS are arranged to be shared in string units SU0 to SU3 separated as units that can be individually driven by the plurality of selection gate lines SGD0 to SGD3 respectively. In the block BLK, (n+1) pieces of (n is an integer of 1 or greater) bit lines BL0 to BLn are provided to be shared. Note that FIG. 2 illustrates, as an example, a case where there are four word lines WL0 to WL3, and the number of word lines WL is not limited to this number.

In the block BLK, (n+1) pieces of memory strings MST are arranged in a row direction. The (n+1) pieces of memory strings MST correspond to (n+1) pieces of bit lines BL0 to BLn, and the memory strings MST are connected to the corresponding bit lines BL0 to BLn.

In each memory string MST, memory cells MT0 to MT3 and selection transistors DST and SST are provided in a column direction. Each of the memory cells MT0 to MT3 is, for example, one transistor. The memory cells MT0 to MT3 are connected in series.

In addition, each of the selection transistors DST and SST is, for example, one transistor. The drain-side selection transistor DST is connected in series to the memory cell MT3 located nearest to a drain among the memory cells MT0 to MT3, and the source-side selection transistor SST is connected in series to the memory cell MT0 located nearest to a source among the memory cells MT0 to MT3. Thus, each memory string MST is configured as above described.

In the memory string MST, the word lines WL0 to WL3 are connected to the control gates of the memory cells MT0 to MT3, respectively. One end of each memory string MST is connected to the bit line BL via the drain-side selection transistor DST, and the other end of each memory string MST is connected to the source line SL via the source-side selection transistor SST.

In the case where one bit is stored in one memory cell in each memory string MST, one memory group MCG can be configured by, for example, (n+1) pieces of memory cells MT connected to the word line WL. Note that when a multi-value of p bits (p is an integer of 2 or greater) is stored in one memory cell, a maximum of “p” pieces of memory groups MCG can be configured by, for example, (n+1) pieces of memory cells MT connected to the word line WL.

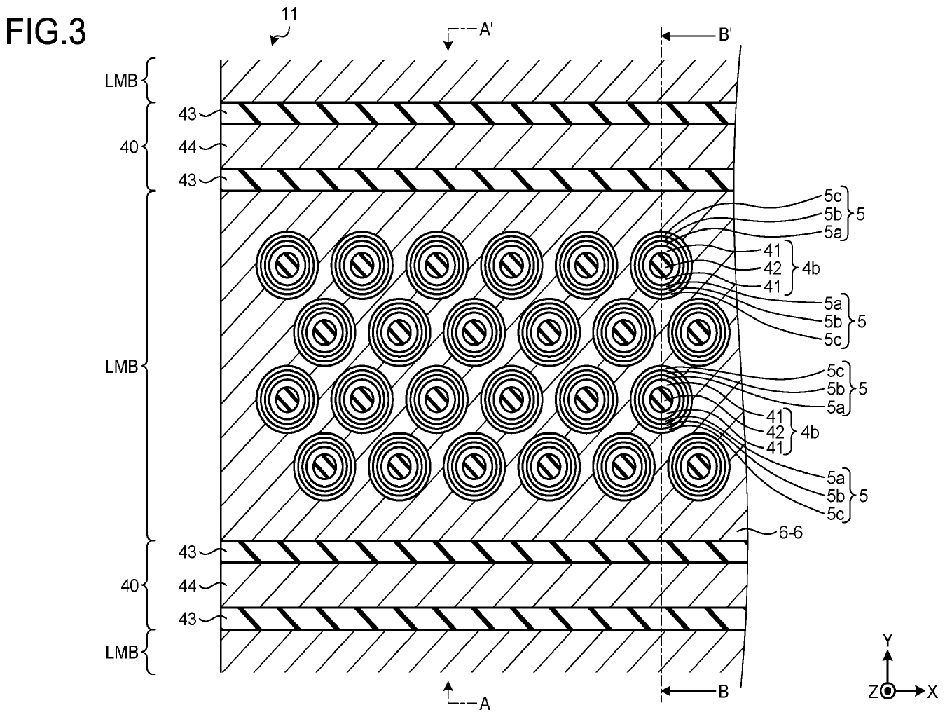

Next, a specific configuration for the memory cell array 2 will be described with reference to FIG. 3 and FIG. 4. FIG. 3 is a diagram illustrating a planar configuration of the memory cell array 2 and illustrates a cross section (an XY cross section) when the memory cell array 2 in FIG. 1 is cut in a plane direction (an XY direction) along the line A-A′. FIG. 4 is a diagram illustrating a cross-sectional configuration of the memory cell array 2 and illustrates a cross section (a YZ cross section) when the memory cell array 2 in FIG. 3 is cut in a vertical direction (a YZ direction) along the line B-B′.

As illustrated in FIG. 3 and FIG. 4, the memory cell array 2 has a configuration in which the columnar bodies 4 are two-dimensionally arranged in the XY direction on the substrate 3 and the stacked body LMB is penetrated by the columnar bodies 4 to form a three-dimensional memory cell arrangement.

The substrate 3 illustrated in FIG. 4 has a semiconductor region (well region) 3a, a semiconductor region 3b, a semiconductor region 3c, and a semiconductor region 3d. The semiconductor region 3a, the semiconductor region 3b, and the semiconductor region 3d each contain impurity of a first conductivity type. The semiconductor region 3c contains impurity of a second conductivity type. The second conductivity type is a conductivity type opposite to the first conductivity type. For example, where the first conductivity type is a P-type and the second conductivity type is an N-type, the impurity of the first conductivity type may be boron, and the impurity of the second conductivity type may be arsenic. Each of the semiconductor regions 3a to 3d will be described later in detail.

On the substrate 3, as illustrated in FIG. 3, a plurality of stacked bodies LMB can be arranged. The plurality of stacked bodies LMB can be arranged in parallel in the Y direction with the separating portion 40 interposed therebetween. In separating portions 40, at least surfaces disposed in contact with the stacked bodies LMB are made of an insulating material, thus electrically separating the plurality of stacked bodies LMB. Each separating portion 40 is adjacent to stacked bodies LMB in the Y direction, on both its sides in the Y direction, and has a substantially fin shape extending in the X direction and the Z direction.

The separating portions 40 are arranged between the plurality of stacked bodies LMB and electrically separate the plurality of stacked bodies LMB. Each separating portion 40 has, as a separating member, an insulating member 43 and an electrode member 44. The electrode member 44 has a substantially fin shape extending in the X direction and the Z direction. The −Z-side end (the bottom surface) of the electrode member 44 is in contact with the semiconductor region 3c of the substrate 3. At least the regions, facing the stacked bodies LMB, of the main surfaces of the electrode member 44 are respectively covered with insulating members 43 each of which has a substantially fin shape extending in the X direction and the Z direction. The electrode member 44 functions as the source line SL.

Each columnar body 4 has a columnar lower portion 4a and a columnar upper portion 4b. The columnar lower portion 4a is arranged on the substrate 3. The columnar lower portion 4a is formed of a material containing a semiconductor (for example, silicon) as a main component and contains impurity of the first conductivity type. Where the first conductivity type is P-type, the impurity of the first conductivity type may be boron. The columnar lower portion 4a may contain the impurity of the first conductivity type at a concentration substantially equal to the concentration of the impurity of the first conductivity type in the semiconductor region 3b.

The columnar upper portion 4b is arranged on the columnar lower portion 4a. The columnar upper portion 4b has a semiconductor column 41 and a core insulating film 42. The core insulating film 42 is arranged near the central axis of the columnar body 4 and extends along the central axis of the columnar body 4. The core insulating film 42 can be formed of a material containing an insulator (for example, silicon oxide) as a main component. The core insulating film 42 has a substantially I shape in a ZY cross-sectional view and a substantially I shape in a ZX cross-sectional view. The semiconductor column 41 is arranged so as to surround the core insulating film 42 from outside, and extends along the central axis of the columnar body 4. The semiconductor column 41 has a substantially cylindrical shape with a closed bottom. The columnar upper portion 4b has a substantially I shape in a ZY cross-sectional view and a substantially I shape in a ZX cross-section view.

The semiconductor column 41 includes a channel region (an active region) in the memory string MST and can be formed of a material containing as a main component a semiconductor (for example, polysilicon) substantially containing no impurity.

In the Z direction, the columnar lower portion 4a is located between the columnar upper portion 4b and the substrate 3 and is in contact with the semiconductor column 41 of the columnar upper portion 4b and also in contact with the semiconductor regions 3b, 3d of the substrate 3. Thereby, the columnar lower portion 4a can electrically connect the semiconductor column 41 and the semiconductor regions 3b, 3d, and forms a semiconductor channel for the memory string MST together with the semiconductor column 41. The columnar lower portion 4a functions as a channel region in the source-side selection transistor SST.

An insulating film 5 is disposed between the stacked body LMB and the semiconductor column 41 and surrounds the semiconductor column 41 in a plan view (see FIG. 3). The insulating film 5 covers the side surface of the semiconductor column 41. The insulating film 5 is configured to have a charge storage capability and has, for example, a three-layer structure of an ONO type in which a charge storage film is sandwiched between a pair of insulating films (a tunnel insulating film and a block insulating film). As illustrated in FIG. 3, the insulating film 5 may have a three-layer structure having an insulating layer 5a, an insulating layer 5b, and an insulating layer 5c in that order from the semiconductor column 41 side. The insulating layer 5a can be formed of a material containing an oxide (for example, a silicon oxide) as a main component. The insulating layer 5b can be formed of a material containing a nitride (for example, a silicon nitride) as a main component. The insulating layer 5c can be formed of a material containing an oxide (for example, a silicon oxide, a metal oxide, or a stack thereof) as a main component.

An insulating film 9 is provided between a conductive film 6-1 and the columnar lower portion 4a. The insulating film 9 can be formed of a material containing an oxide (for example, silicon oxide) as a main component.

In the stacked body LMB, a conductive film 6 and an insulating film 7 are alternately layered. In the case of FIG. 4, an insulating film 7-1, the conductive film 6-1, an insulating film 7-2, a conductive film 6-2, an insulating film 7-3, a conductive film 6-3, an insulating film 7-4, a conductive film 6-4, an insulating film 7-5, a conductive film 6-5, an insulating film 7-6, and a conductive film 6-6 are formed in order on the substrate 3. Each conductive film 6 can be formed of a material containing a conductive material (for example, a metal such as tungsten) as a main component. Each insulating film 7 can be formed of a material containing an insulator (for example, a semiconductor oxide such as a silicon oxide) as a main component. The conductive film 6-1 functions as the selection gate line SGS. The conductive film 6-2 functions as the word line WL0. The conductive film 6-3 functions as the word line WL1. The conductive film 6-4 functions as the word line WL2. The conductive film 6-5 functions as the word line WL3. The conductive film 6-6 functions as the selection gate line SGD. Note that a portion, above the conductive film 6-5, of the insulating film 5 may be a single-layer film of the insulating layer 5a.

As illustrated in FIG. 4, the source-side selection transistor SST is formed at a position where the conductive film 6-1 intersects the columnar lower portion 4a and the insulating film 9. A memory cell MT0 is formed at a position where the conductive film 6-2 intersects the semiconductor column 41 and the insulating film 5. The memory cell MT1 is formed at a position where the conductive film 6-3 intersects the semiconductor column 41 and the insulating film 5. A memory cell MT2 is formed at a position where the conductive film 6-4 intersects the semiconductor column 41 and the insulating film 5. A memory cell MT3 is formed at a position where the conductive film 6-5 intersects the semiconductor column 41 and the insulating film 5. A drain-side selection transistor DST is formed at a position where the conductive film 6-6 intersects the semiconductor column 41 and the insulating film 5.

An interlayer insulating film 8 is provided on the stacked body LMB. The interlayer insulating film 8 can be formed of a material containing an insulator (for example, a semiconductor oxide such as a silicon oxide) as a main component.

On the interlayer insulating film 8, a conductive film 32 is provided. The conductive film 32 functions as a bit line BL. The conductive film 32 can be formed of a material containing a conductive substance (for example, a metal such as tungsten or aluminum) as a main component.

A contact plug 31 is provided between the conductive film 32 and the semiconductor column 41. The contact plug 31 contacts the conductive film 32 at its upper end, contacts the semiconductor column 41 at its lower end, and can electrically connect the conductive film 32 and the semiconductor column 41. The contact plug 31 functions as a bit line contact. The contact plug 31 can be formed of a material containing a conductive substance (for example, a metal such as tungsten) as a main component.

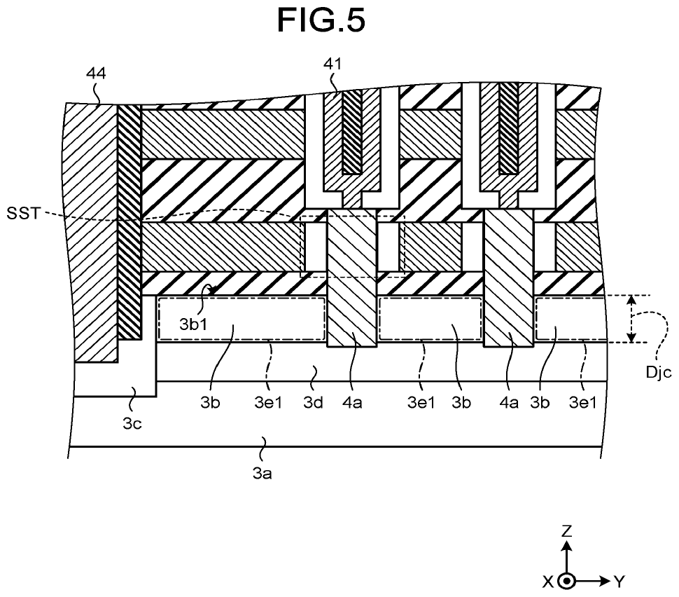

Next, a semiconductor region near the source-side selection transistor will be described with reference to FIG. 5. FIG. 5 is a cross-sectional view illustrating the semiconductor region near the source-side selection transistor. FIG. 5 is an enlarged sectional view of a portion C in FIG. 4.

In the configuration illustrated in FIG. 5, as described above, the columnar lower portion 4a can electrically connect the semiconductor column 41 and the semiconductor regions 3b, 3d and forms the semiconductor channel for the memory string MST together with the semiconductor column 41. The columnar lower portion 4a is a portion on the lower end side (the −Z-side) of the semiconductor channel and functions as a channel region in the source-side selection transistor SST. The columnar lower portion 4a reaches the semiconductor region 3b in the substrate 3. That is, the semiconductor region 3b extends in the XY direction and is connected to the side surface of the columnar lower portion 4a. The semiconductor region 3b is mainly disposed at a position shifted in the XY direction from the columnar lower portion 4a (semiconductor channel). For example, the semiconductor region 3b is disposed in an XY plane between the plurality of columnar lower portions 4a (that is, between the plurality of semiconductor channels). Alternatively, the semiconductor region 3b is disposed in an XY plane between the semiconductor region 3c and the columnar lower portion 4a (that is, between a source line diffusion layer, described later, and the semiconductor channel).

This semiconductor region 3b contains impurity of the first conductivity type. The first conductivity type is, for example, P-type, and an impurity of the first conductivity type is, for example, boron. The semiconductor region 3b contains the impurity of the first conductivity type at a concentration suitable for Vth adjustment of the source-side selection transistor SST. The introduction of the impurity of the first conductivity type into the semiconductor region 3b can be performed by ion-implanting the impurity of the first conductivity type into the vicinity of a surface 3b1 of the substrate 3 in a well formation step. During the ion implantation, lattice defects are formed in and around the semiconductor region 3b and, as a result, interstitial semiconductor atoms (interstitial silicon) are formed between the lattices. The impurity of the first conductivity type in the semiconductor region 3b, for example, binds to interstitial semiconductor atoms (interstitial silicon) and, in a subsequent step such as heat treatment (for example, thermal oxidation during transistor formation, or activation annealing after ion implantation), diffuses in a depth direction within the substrate 3, so that the concentration of the impurity near the surface 3b1 of the substrate 3 may decrease.

Meanwhile, in the substrate 3, a diffusion inhibiting region 3e1 that overlaps the semiconductor region 3b throughout the depth direction of the semiconductor region 3b is provided. The +Z-side surface of the semiconductor region 3b and the +Z-side surface of the diffusion inhibiting region 3e1 may be equal in level in the Z direction and each may form the substrate surface. The columnar lower portion 4a (the lower-end-side portion of the semiconductor channel) reaches the diffusion inhibiting region 3e1 in the substrate 3. That is, the diffusion inhibiting region 3e1 extends in the XY direction and is connected to the side surface of the columnar lower portion 4a. The diffusion inhibiting region 3e1 is mainly disposed in a place shifted in the XY direction from the columnar lower portion 4a (the semiconductor channel). For example, the diffusion inhibiting region 3e1 is disposed in an XY plane between the plurality of columnar lower portions 4a (that is, between the plurality of semiconductor channels). Alternatively, the diffusion inhibiting region 3e1 is disposed in an XY plane between the semiconductor region 3c and the columnar lower portion 4a (that is, between the source line diffusion layer, described layer, and the semiconductor channel). The diffusion inhibiting region 3e1 contains a diffusion inhibiting impurity. This diffusion inhibiting impurity is an impurity that easily binds to interstitial semiconductor atoms (interstitial silicon) formed during ion implantation of the semiconductor region 3b, and may be, for example, carbon. That is, by virtue of the provision of the diffusion inhibiting region 3e1 overlapping the semiconductor region 3b throughout the depth direction of the semiconductor region 3b, the diffusion inhibiting impurity binds to the interstitial semiconductor atoms (the interstitial silicon), thus making it possible to inhibit the impurity of the first conductivity type in the semiconductor region 3b from diffusing in the depth direction. For example, the diffusion inhibiting region 3e1 can inhibit, in a place shifted from the semiconductor channel in the XY direction, diffusion of the impurity of the first conductivity type in the semiconductor region 3b in the −Z direction.

The semiconductor region 3c contains impurity of the second conductivity type. The second conductivity type is a conductivity type opposite to the first conductivity type, for example, N-type, and impurity of the second conductivity type is, for example, arsenic. The semiconductor region 3c is electrically connected to the electrode member 44 functioning as the source line SL, and functions as the source line diffusion layer.

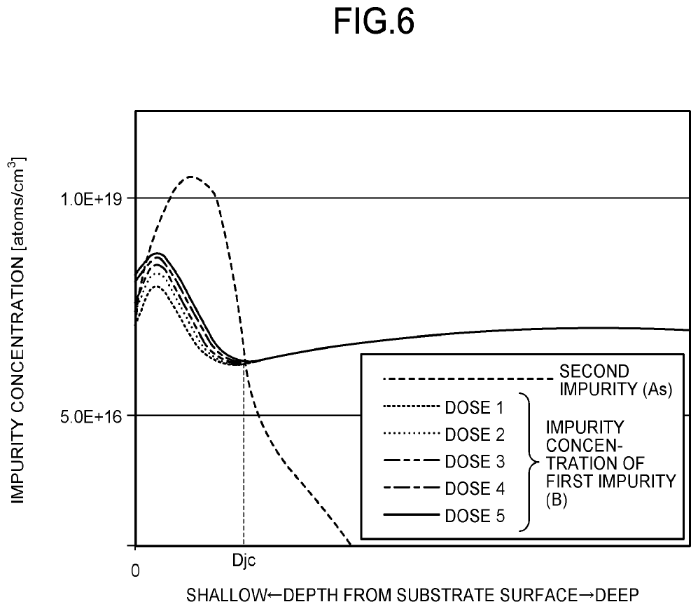

Here, the boundary between the semiconductor regions 3b, 3d, and 3a of the first conductivity type and the semiconductor region 3c of the second conductivity type has impurity concentration profiles as illustrated in FIG. 6. FIG. 6 is a diagram illustrating the respective impurity concentration profiles of the semiconductor regions of the first conductivity type and the semiconductor region of the second conductivity type. In FIG. 6, the vertical axis indicates impurity concentration, and the horizontal axis indicates depth from the surface 3b1 of the substrate 3.

FIG. 6 illustrates, as an example, a case where the semiconductor regions 3b, 3d, 3a of the first conductivity type all contain boron as an impurity and the semiconductor region 3c of the second conductivity type contains arsenic as an impurity. FIG. 6 illustrates the respective concentration profiles of boron in a case where a dose of boron with respect to the vicinity of the surface 3b1 of the substrate 3 is changed (for example, from a dose 1 to a dose 5, wherein the dose 1<the dose 2<the dose 3<the dose 4<the dose 5). Regardless of the dose, each of the boron concentration profiles and the arsenic concentration profile indicated by the broken line illustrated in FIG. 6, generally intersect in a depth Djc from the surface 3b1 of the substrate 3. The depth Djc may be, for example, approximately 150 nm. Note that the concentration profile of the high-concentration second impurity as illustrated in FIG. 6 is found in a local region from below the separating portion 40 to the boundary of the semiconductor region 3c and is not found, for example, in a place near the columnar lower portion 4a. Here, a depth range with a depth of 0 to Djc from the surface 3b1 of the substrate 3 is a place where there is a possibility that a junction leakage may occur between the semiconductor region of the first conductivity type and the semiconductor region of the second conductivity type. In order to inhibit the junction leakage, it is effective to keep the concentration of the impurity (boron) of the first conductivity type low in the range of the depth Djc from the surface 3b1 of the substrate 3.

Meanwhile, at each dose in the semiconductor region 3b, the concentration profile of the impurity of the first conductivity type is extended from the surface 3b1 of the substrate 3, through a depth range lower in concentration than the concentration profile of the second impurity of the second conductivity type, to the depth Djc where the first impurity concentration profile and the second impurity concentration profile intersect in FIG. 6. In addition, the doses are substantially equal in the concentration of the impurity of the first conductivity type in the depth Djc, none is significantly higher than the others, and the concentration of the impurity of the first conductivity type in the depth Djc is reduced to a low level. In addition, in the substrate 3, the diffusion inhibiting region 3e1 overlapping the semiconductor region 3b throughout the depth direction of the semiconductor region 3b is provided. Thus, the diffusion inhibiting impurity binds to interstitial semiconductor atoms (interstitial silicon) in the semiconductor region 3b, making it possible to inhibit the impurity of the first conductivity type in the semiconductor region 3b from diffusing in the depth direction.

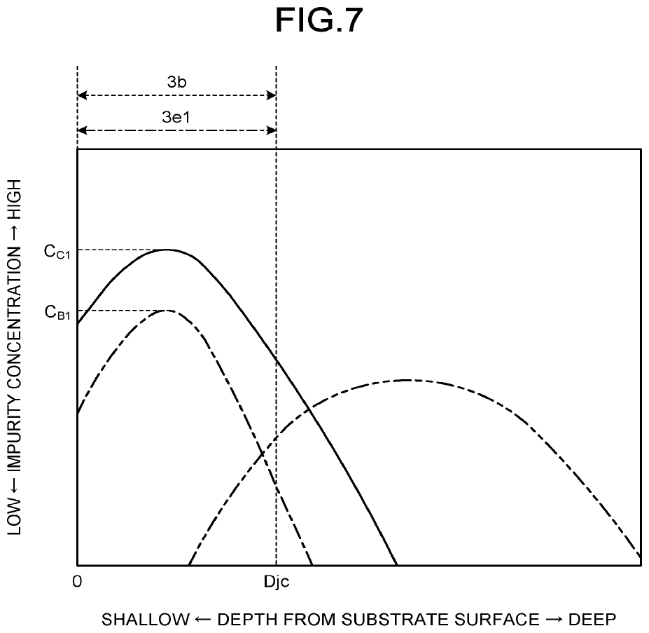

The diffusion inhibiting impurity in the diffusion inhibiting region 3e1 may have a concentration profile as illustrated in FIG. 7. FIG. 7 is a diagram illustrating an impurity concentration profile of the diffusion inhibiting region 3e1. In FIG. 7, the vertical axis indicates impurity concentration and the horizontal axis indicates depth from the surface 3b1 of the substrate 3. In FIG. 7, the concentration profile of the diffusion inhibiting impurity is plotted by a solid line. For comparison, the concentration profile of an impurity of the first conductivity type mainly present in the semiconductor region 3b is plotted by a dashed-dotted line, and the concentration profile of an impurity of the first conductivity type mainly present in the semiconductor region (the well region) 3a is plotted by a two-dot chain line.

As illustrated in FIG. 7, the concentration profile of the diffusion inhibiting impurity (carbon) is higher than the concentration profile of the impurity (boron) of the first conductivity type, from the surface 3b1 of the substrate 3 to the depth Djc. That is, in a range of depth 0 to Djc from the surface 3b1, a region where the concentration profile of the diffusion inhibiting impurity (carbon) is higher than the concentration profile of the impurity (boron) of the first conductivity type effectively functions as a diffusion inhibiting region 3e1 that inhibits diffusion of the impurity of the first conductivity type in the depth direction.

The concentration profile of the impurity (boron) of the first conductivity type has a peak in the semiconductor region 3b. That is, the concentration profile of the impurity (boron) of the first conductivity type has a peak in an XY plane shifted in the XY direction from the columnar lower portion 4a and at a Z position between the surface 3b1 and the depth Djc. The concentration profile of the diffusion inhibiting impurity (carbon) has a peak in the diffusion inhibiting region 3e1. That is, the concentration profile of the diffusion inhibiting impurity (carbon) has a peak in the XY plane shifted in the XY direction from the columnar lower portion 4a and at the Z position between the surface 3b1 and the depth Djc.

The peak C_{C1} of the concentration profile of the diffusion inhibiting impurity (carbon) is higher in concentration than the peak C_{B1} of the concentration profile of the impurity (boron) of the first conductivity type. The peak C_{C1} of the concentration profile of the diffusion inhibiting impurity (carbon) may be higher in concentration than the peak C_{B1} of the concentration profile of the impurity (boron) of the first conductivity type by one digit or more in the unit of atoms/cm³. For example, the peak of the concentration profile of the impurity (boron) of the first conductivity type may have a concentration of 5×10¹⁶ atoms/cm³ or higher and 1×10¹⁹ atoms/cm³ or lower. The peak of the concentration profile of the diffusion inhibiting impurity (carbon) may have a concentration of 1×10¹⁹ atoms/cm³ or higher, preferably, 1×10²⁰ atoms/cm³ or higher.

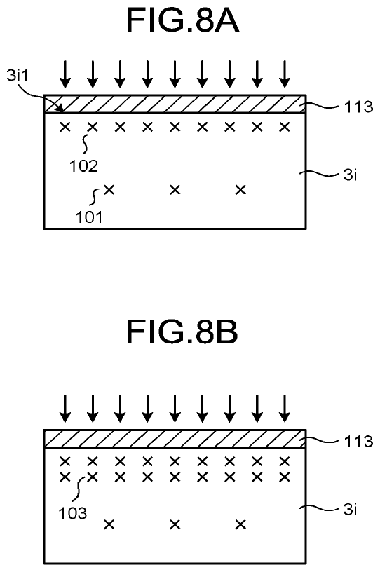

Next, a manufacturing method for the semiconductor device 1 will be described with reference to FIG. 8A, FIG. 8B, and FIG. 4. FIGS. 8A and 8B are process cross-sectional views illustrating the manufacturing method for the semiconductor device 1. FIG. 4 is a cross-sectional view illustrating the configuration of the memory cell array 2 but is diverted to a cross-sectional view illustrating the manufacturing method for the semiconductor device 1.

In a step illustrated in FIG. 8A, a substrate 3i is prepared. The substrate 3i is formed of a material containing a semiconductor (for example, silicon) as a main component. Then, a sacrificial insulating film 113 for performing ion implantation in a subsequent step is formed on the substrate 3i. The sacrificial insulating film 113 is formed of a semiconductor oxide film (for example, a silicon oxide film).

Impurity 101 of the first conductivity type is introduced into the substrate 3i and to a predetermined depth at which a well region is to be formed. Specifically, boron ions are implanted into the substrate 3i through the sacrificial insulating film 113 and to a predetermined depth by an ion implantation method. In addition, impurity 102 of a first conductivity type is introduced into the substrate 3i and in the vicinity of a surface 3i1 thereof. Specifically, boron ions are implanted into the substrate 3i through the sacrificial insulating film 113 and in the vicinity of the surface 3i1 thereof by an ion implantation method. At this time, lattice defects are formed in and around the region into which the impurity 102 has been implanted and consequently interstitial semiconductor atoms (interstitial silicon) are formed between the lattices.

In the step illustrated in FIG. 8B, a diffusion inhibiting impurity 103 is introduced into the substrate 3i and in the vicinity of the surface 3i1 thereof. Specifically, carbon ions are implanted into the substrate 3i through the sacrificial insulating film 113 and in the vicinity of the surface 3i1 thereof by an ion implantation method. Consequently, a diffusion inhibiting region 3e1 is formed in the region into which the impurity 103 has been implanted (see FIG. 5). This impurity 103 is an impurity that easily binds to interstitial semiconductor atoms (interstitial silicon). Then, annealing for recovering damage (such as crystal defect) in the semiconductor substrate 3i, resulting from the ion implantation, is performed. Thus, a semiconductor region (a well region) 3a is formed in the region into which the impurity 101 has been implanted, and a semiconductor region 3b is formed in the region into which the impurity 102 has been implanted (see FIG. 5). At this time, the impurity 103 binds to the interstitial semiconductor atoms (interstitial silicon), and the diffusion of the impurity 102 in the depth direction can be inhibited.

After that, the sacrificial insulating film 113 is removed off with diluted hydrofluoric acid. On the substrate 3 after the removal of the sacrificial insulating film 113, a stacked body is formed by alternately layering an insulating film 7 (for example, a silicon oxide film) and a second insulating film (for example, a silicon nitride film). In addition, a memory hole penetrating through the stacked body and reaching the substrate 3 is formed. A columnar lower portion 4a is formed by epitaxially growing a semiconductor (for example, silicon) on the bottom surface of the memory hole. At this time, an impurity (boron) of the first conductivity type may be introduced into the columnar lower portion 4a. An insulating film 5 is deposited on the side surface and bottom surface of the memory hole in which the columnar lower portion 4a is formed, and a portion, covering the bottom surface of the memory hole, of the insulating film 5 is selectively removed. Thereafter, a semiconductor and an insulator are deposited in order in the memory hole to form a semiconductor column 41 and a core insulating film 42.

Then, a groove for dividing the stacked body is formed, and an impurity of the second conductivity type is introduced into the place and to the depth where the semiconductor region 3c illustrated in FIG. 4 is to be provided. Specifically, arsenic ions are implanted, through the groove, into the place and to the depth where the semiconductor region 3c is to be provided in the substrate 3, by an ion implantation method. Then, annealing is performed, and the semiconductor region 3c is formed. In addition, a second insulating film in the stacked body is selectively removed through the groove. Then, thermal oxidation or the like for forming a gate oxide film for a source-side selection transistor is performed, and a conductive material is filled in a portion from which the second insulating film has been removed to form a conductive film 6. Thus, as illustrated in FIG. 4, a stacked body LMB is obtained, in which an insulating film 7-1, a conductive film 6-1, an insulating film 7-2, a conductive film 6-2, an insulating film 7-3, a conductive film 6-3, an insulating film 7-4, a conductive film 6-4, the insulating film 7-5, a conductive film 6-5, an insulating film 7-6, and a conductive film 6-6 are deposited in order.

As described above, in the present embodiment, in the semiconductor device 1, the region (the diffusion inhibiting region 3e1).containing the impurity (e.g., carbon) that inhibits diffusion of the impurity (e.g., boron) of the first conductivity type is formed in the semiconductor region 3b containing the impurity of the first conductivity type. For example, the diffusion inhibiting region 3e1 is disposed so as to overlap the semiconductor region 3b throughout the depth direction of the semiconductor region 3b. At this time, the columnar lower portion 4a (the lower-end-side portion of the semiconductor channel) reaches the diffusion inhibiting region 3e1 in the substrate 3. Thus, diffusion of the impurity of the first conductivity type in the substrate 3 can be inhibited and, even when a dose during ion implantation is relatively small, the concentration of the impurity of the first conductivity type near the surface 3b1 of the substrate 3 can be secured (see FIG. 6). Therefore, the threshold voltage of the source-side selection transistor SST can be optimized.

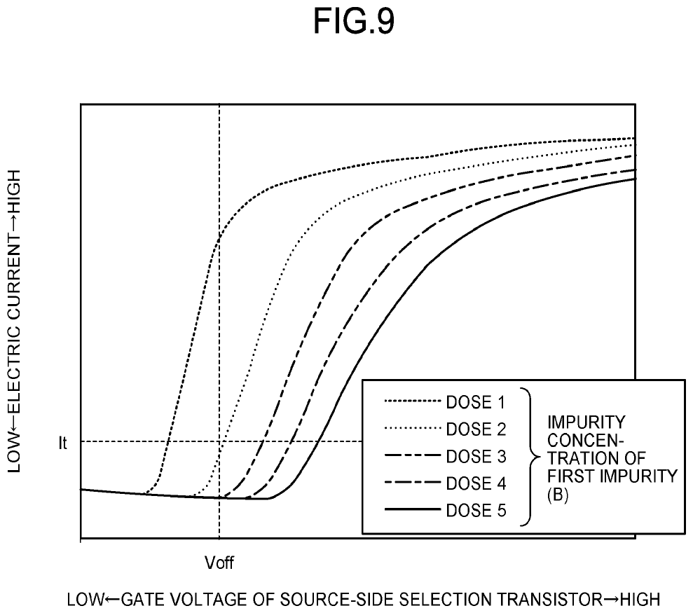

For example, the voltage-current characteristics of the source-side selection transistor SST when the diffusion inhibiting region 3e1 is disposed so as to overlap the semiconductor region 3b throughout the depth direction of the semiconductor region are exhibited as illustrated in FIG. 9. FIG. 9 is a diagram illustrating the voltage-current characteristics of the source-side selection transistor SST when the dose of the impurity of the first conductivity type in ion implantation is changed (see FIG. 6). The vertical axis indicates the drain current of the source-side selection transistor SST and the horizontal axis indicates the gate voltage (SGS voltage) of the source-side selection transistor SST. It can be seen that the desired cutoff characteristics can be satisfied under the condition that the dose of boron is dose 2 to dose 5. That is, in the voltage-current characteristics of the source-side selection transistor SST, even if the dose of boron is relatively small, the current value can be reduced lower than the upper limit current It satisfying the desired cut-off characteristic with respect to the cut-off gate voltage (SGS voltage) Voff of the source-side selection transistor SST.

In addition, in the present embodiment, because diffusion of the impurity of the first conductivity type in the substrate 3 can be inhibited, the concentration of the impurity of the first conductivity type in the semiconductor region 3b excluding the surface 3b1 of the substrate 3 can be restricted. Thus, the junction leak between the semiconductor region of the first conductivity type and the semiconductor region of the second conductivity type (source line diffusion layer) can be inhibited.

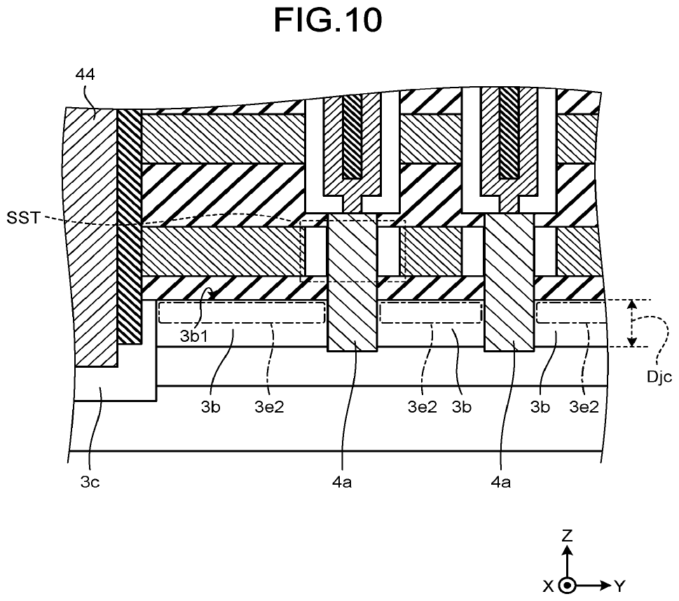

As illustrated in FIG. 10, a diffusion inhibiting region 3e2 may be disposed so as to overlap the semiconductor region 3b on the surface 3b1 side of the substrate 3 in the depth direction of the semiconductor region 3b. FIG. 10 is a cross-sectional view illustrating a semiconductor region near a source-side selection transistor in a first modified example of the embodiment. In this case, the +Z-side surface of the semiconductor region 3b and the +Z-side surface of the diffusion inhibiting region 3e2 may be equal in level in the Z direction and each may form a substrate surface. The columnar lower portion 4a (the lower-end-side portion of the semiconductor channel) reaches the diffusion inhibiting region 3e2 in the substrate 3. The diffusion inhibiting region 3e2 is mainly disposed in a place shifted in the XY direction from the columnar lower portion 4a (the semiconductor channel). For example, the diffusion inhibiting region 3e2 is disposed in an XY plane between the plurality of columnar lower portions 4a (that is, between the plurality of semiconductor channels). Alternatively, the diffusion inhibiting region 3e2 is disposed in an XY plane between the semiconductor region 3c and the columnar lower portion 4a (that is, between the source line diffusion layer and the semiconductor channel). The diffusion inhibiting impurity in the diffusion inhibiting region 3e2 binds to the interstitial semiconductor atoms (interstitial silicon) on the surface 3b1 side of the semiconductor region 3b, thus making it possible to prevent the impurity of the first conductivity type in the semiconductor region 3b from diffusing in the depth direction. For example, the diffusion inhibiting region 3e2 can inhibit, in a place shifted from the semiconductor channel in the XY direction, diffusion of the impurity of the first conductivity type in the semiconductor region 3b in the −Z direction. This also makes it possible to reduce the concentration of the impurity (boron) of the first conductivity type in the depth Djc while optimizing the threshold voltage of the source-side selection transistor.

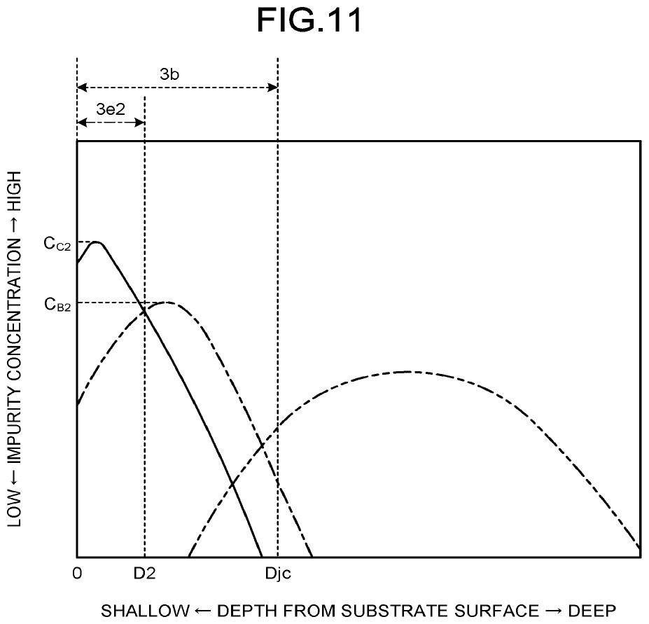

At this time, the diffusion inhibiting impurity in the diffusion inhibiting region 3e2 may have a concentration profile as illustrated in FIG. 11. FIG. 11 is a diagram illustrating an impurity concentration profile of the diffusion inhibiting region 3e2 in the first modified example of the embodiment. In FIG. 11, the vertical axis indicates impurity concentration, and the horizontal axis indicates depth from the surface 3b1 of the substrate 3. In FIG. 11, the concentration profile of the diffusion inhibiting impurity is plotted by a solid line. For comparison, the concentration profile of an impurity of the first conductivity type mainly present in the semiconductor region 3b is plotted by a dashed-dotted line, and the concentration profile of an impurity of the first conductivity type mainly present in the semiconductor region (the well region) 3a is plotted by a two-dot chain line.

As illustrated in FIG. 11, the concentration profile of the diffusion inhibiting impurity (carbon) is higher than the concentration profile of the impurity (boron) of the first conductivity type, from the surface 3b1 of the substrate 3 to a depth D2. The depth D2 is shallower than the depth Djc. That is, in a range of depth 0 to D2 from the surface 3b1, a region where the concentration profile of the diffusion inhibiting impurity (carbon) is higher than the concentration profile of the impurity (boron) of the first conductivity type effectively functions as a diffusion inhibiting region 3e2 that inhibits diffusion of the impurity of the first conductivity type in the depth direction.

The concentration profile of the impurity (boron) of the first conductivity type has a peak in the semiconductor region 3b. That is, the concentration profile of the impurity (boron) of the first conductivity type has a peak in an XY plane shifted in the XY direction from the columnar lower portion 4a and at a Z position between the surface 3b1 and the depth Djc. The concentration profile of the diffusion inhibiting impurity (carbon) has a peak in the diffusion inhibiting region 3e2. That is, the concentration profile of the diffusion inhibiting impurity (carbon) has a peak in the XY plane shifted in the XY direction from the columnar lower portion 4a and at the Z position between the surface 3b1 and the depth Djc. In addition, the concentration profile of the diffusion inhibiting impurity (carbon) has a peak at a depth (Z position on the +Z side) shallower than the concentration profile of the impurity (boron) of the first conductivity type.

The peak C_{C2} of the concentration profile of the diffusion inhibiting impurity (carbon) is higher in concentration than the peak C_{B2} of the concentration profile of the impurity (boron) of the first conductivity type. The peak C_{C2} of the concentration profile of the diffusion inhibiting impurity (carbon) may be higher than the peak C_{B2} of the concentration profile of the impurity (boron) of the first conductivity type by one digit or more in the unit of atoms/cm³. For example, the peak C_{B2} of the concentration profile of the impurity (boron) of the first conductivity type may have a concentration of 5×10¹⁶ atoms/cm³ or higher and 1×10¹⁹ atoms/cm³ or lower. The peak C_{C2} of the concentration profile of the diffusion inhibiting impurity (carbon) may have a concentration of 1×10¹⁹ atoms/cm³ or higher, preferably, 1×10²⁰ atoms/cm³ or higher.

Even with such a configuration, diffusion of the impurity of the first conductivity type in the substrate 3 can be inhibited. Consequently, the threshold voltage of the source-side selection transistor SST can be optimized, and the junction leakage between the semiconductor region of the first conductivity type and the semiconductor region of the second conductivity type (source line diffusion layer) can be inhibited.

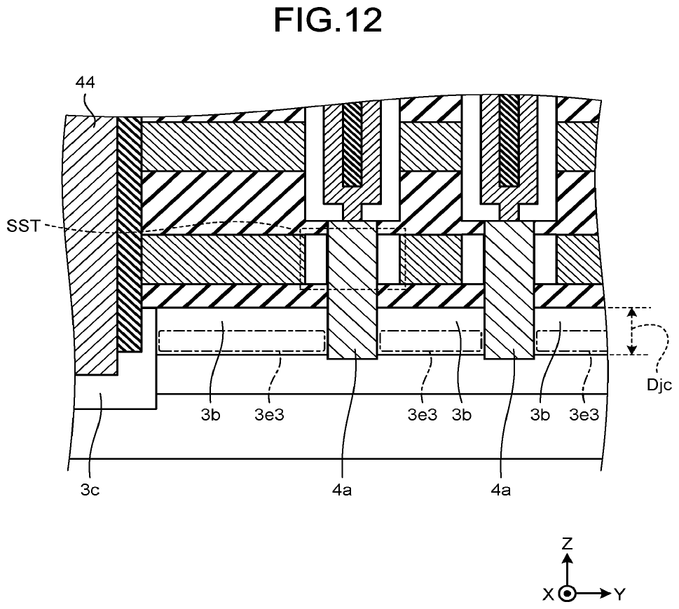

Alternatively, as illustrated in FIG. 12, a diffusion inhibiting region 3e3 may be disposed so as to overlap the semiconductor region 3b on the depth Djc side in the depth direction of the semiconductor region 3b. FIG. 12 is a cross-sectional view illustrating a semiconductor region near a source-side selection transistor in a second modified example of the embodiment. In this case, the +Z-side surface of the diffusion inhibiting region 3e3 may have a surface position between the +Z-side surface of the semiconductor region 3b and a position at the depth Djc in the Z direction. The columnar lower portion 4a (the lower-end-side portion of the semiconductor channel) reaches the diffusion inhibiting region 3e3 in the substrate 3. The diffusion inhibiting region 3e3 is mainly disposed in a place shifted in the XY direction from the columnar lower portion 4a (the semiconductor channel). For example, the diffusion inhibiting region 3e3 is disposed in an XY plane between the plurality of columnar lower portions 4a (that is, between the plurality of semiconductor channels). Alternatively, the diffusion inhibiting region 3e3 is disposed in an XY plane between the semiconductor region 3c and the columnar lower portion 4a (that is, between the source line diffusion layer and the semiconductor channel). The diffusion inhibiting impurity in this diffusion inhibiting region 3e3 binds to the interstitial semiconductor atoms (interstitial silicon) in the depth Djc side of the semiconductor region 3b, thus making it possible to prevent the impurity of the first conductivity type in the semiconductor region 3b from diffusing in the depth direction. For example, the diffusion inhibiting region 3e3 can inhibit, in a place shifted from the semiconductor channel in the XY direction, diffusion of the impurity of the first conductivity type in the semiconductor region 3b in the −Z direction. This also makes it possible to reduce the concentration of the impurity (boron) of the first conductivity type in the depth Djc while optimizing the threshold voltage of the source-side selection transistor.

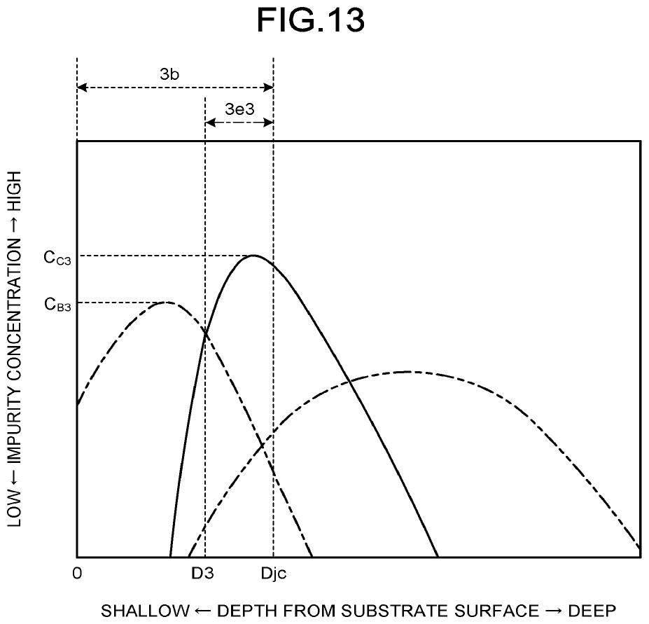

At this time, the diffusion inhibiting impurity in the diffusion inhibiting region 3e3 may have a concentration profile as illustrated in FIG. 13. FIG. 13 is a diagram illustrating an impurity concentration profile of the diffusion inhibiting region 3e3 in the second modified example of the embodiment. In FIG. 13, the vertical axis indicates impurity concentration, and the horizontal axis indicates depth from the surface 3b1 of the substrate 3. In FIG. 13, the concentration profile of the diffusion inhibiting impurity is plotted by a solid line. For comparison, the concentration profile of an impurity of the first conductivity type mainly present in the semiconductor region 3b is plotted by a dashed-dotted line, and the concentration profile of an impurity of the first conductivity type mainly present in the semiconductor region (the well region) 3a is plotted by a two-dot chain line.

As illustrated in FIG. 13, the concentration profile of the diffusion inhibiting impurity (carbon) is higher than the concentration profile of the impurity (boron) of the first conductivity type, from a depth D3 deeper than the surface 3b1 of the substrate 3 to the depth Djc. The depth D3 is shallower than the depth Djc. That is, in a range of depth D3 to Djc from the surface 3b1, a region where the concentration profile of the diffusion inhibiting impurity (carbon) is higher than the concentration profile of the impurity (boron) of the first conductivity type effectively functions as a diffusion inhibiting region 3e3 that inhibits diffusion of the impurity of the first conductivity type in the depth direction.

The concentration profile of the impurity (boron) of the first conductivity type has a peak in the semiconductor region 3b. That is, the concentration profile of the impurity (boron) of the first conductivity type has a peak in an XY plane shifted in the XY direction from the columnar lower portion 4a and at a Z position between the surface 3b1 and the depth Djc. The concentration profile of the diffusion inhibiting impurity (carbon) has a peak in the diffusion inhibiting region 3e3. That is, the concentration profile of the diffusion inhibiting impurity (carbon) has a peak in the XY plane shifted in the XY direction from the columnar lower portion 4a and at the Z position between the surface 3b1 and the depth Djc. In addition, the concentration profile of the diffusion inhibiting impurity (carbon) has a peak at a depth (Z position on the −Z side) deeper than the concentration profile of the impurity (boron) of the first conductivity type.

The peak C_{C3} of the concentration profile of the diffusion inhibiting impurity (carbon) is higher in concentration than the peak C_{B3} of the concentration profile of the impurity (boron) of the first conductivity type. The peak C_{C3} of the concentration profile of the diffusion inhibiting impurity (carbon) may be higher than the peak C_{B3} of the concentration profile of the impurity (boron) of the first conductivity type by one digit or more in the unit of atoms/cm³. For example, the peak C_{B3} of the concentration profile of the impurity (boron) of the first conductivity type may have a concentration of 5×10¹⁶ atoms/cm³ or higher and 1×10¹⁹ atoms/cm³ or lower. The peak C_{C3} of the concentration profile of the diffusion inhibiting impurity (carbon) may have a concentration of 1×10¹⁹ atoms/cm³ or higher, preferably, 1×10²⁰ atoms/cm³ or higher.

Even with such a configuration, diffusion of the impurity of the first conductivity type in the substrate 3 can be inhibited. Consequently, the threshold voltage of the source-side selection transistor SST can be optimized, and the junction leakage between the semiconductor region of the first conductivity type and the semiconductor region of the second conductivity type (source line diffusion layer) can be inhibited.

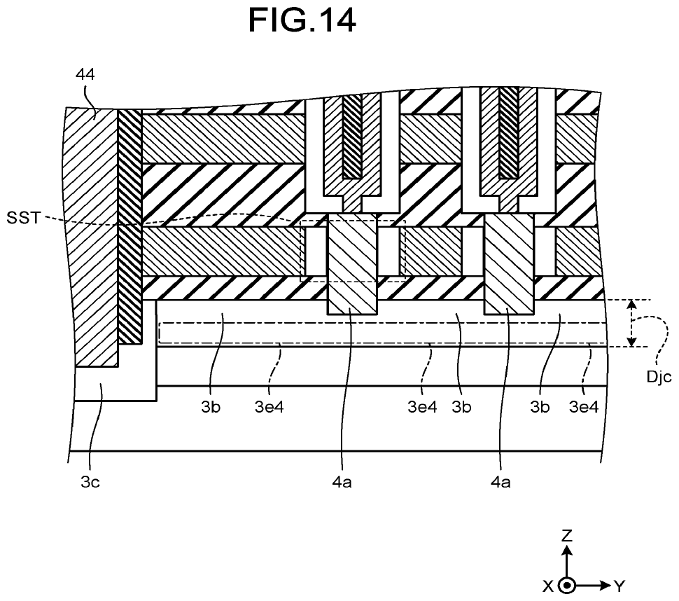

Alternatively, a configuration as illustrated in FIG. 14 also will suffice, in which a diffusion inhibiting region 3e4 is disposed so as to overlap the semiconductor region 3b on the depth Djc side in the depth direction of the semiconductor region 3b and the columnar lower portion 4a reaches a +Z-side position from the diffusion inhibiting region 3e4 in the semiconductor region 3b and does not reach the diffusion inhibiting region 3e4. FIG. 14 is a cross-sectional view illustrating a semiconductor region near a source-side selection transistor in a third modified example of the embodiment. In this case, the +Z-side surface of the diffusion inhibiting region 3e4 may have a surface position between the +Z-side surface of the semiconductor region 3b and a position at the depth Djc in the Z direction. The diffusion inhibiting region 3e4 is mainly disposed in a place shifted in the XY direction from the columnar lower portion 4a (the semiconductor channel) and in a place corresponding to the columnar lower portion 4a (the semiconductor channel). The diffusion inhibiting region 3e4 is not connected to the side surface of the columnar lower portion 4a but extends in the XY direction below the −Z-side end of the columnar lower portion 4a. For example, the diffusion inhibiting region 3e4 is disposed in the XY plane located between the plurality of columnar lower portions 4a (that is, between the plurality of semiconductor channels) and also located in the XY plane on the −Z sides of the columnar lower portions 4a (semiconductor channels). Alternatively, the diffusion inhibiting region 3e4 is disposed in the XY plane located between the semiconductor region 3c and the columnar lower portion 4a (i.e., between the source line diffusion layer and the semiconductor channel) and also located in the XY plane on the −Z sides of the columnar lower portions 4a (semiconductor channels).

Also, in this configuration, the diffusion inhibiting region 3e4 can inhibit, in a place shifted from the semiconductor channel in the XY direction, diffusion of the impurity of the first conductivity type in the semiconductor region 3b in the −Z direction. This also makes it possible to reduce the concentration of the impurity (boron) of the first conductivity type in the depth Djc while optimizing the threshold voltage of the source-side selection transistor.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a stacked body disposed above a substrate and in which a plurality of conductive films are interspatially arranged in a layering direction;
a first region disposed in the substrate and including a peak of a concentration profile of a first impurity of a first conductivity type, the first region extending from a surface of the substrate, through a depth range including a concentration profile of a second impurity of a second conductivity type higher in concentration than the concentration profile of the first impurity having the peak, to a depth of an intersection of the concentration profile of the first impurity having the peak and the concentration profile of the second impurity;
a second region disposed in the substrate and including a concentration profile of a third impurity, the second region overlapping at least part of the first region in the layering direction, the concentration profile of the third impurity being higher in concentration than the concentration profile of the first impurity throughout a depth direction of the second region; and
a semiconductor channel penetrating the stacked body in the layering direction and one end thereof reaches the first region and the second region.

2. The semiconductor device according to claim 1, wherein
the second region includes a peak of the concentration profile of the third impurity and overlaps the first region throughout a depth direction of the first region.

3. The semiconductor device according to claim 1, wherein
the second region includes a peak of the concentration profile of the third impurity and overlaps the first region on a side of the surface of the substrate in a depth direction of the first region.

4. The semiconductor device according to claim 1, wherein
the second region includes a peak of the concentration profile of the third impurity and overlaps the first region on a side of the intersection in a depth direction of the first region.

5. The semiconductor device according to claim 1, wherein
a peak of the concentration profile of the third impurity is higher in concentration than the peak of the concentration profile of the first impurity.

6. The semiconductor device according to claim 5, wherein
the peak of the concentration profile of the third impurity is higher in concentration than the peak of the concentration profile of the first impurity by one digit or more in a unit of atoms/cm³.

7. The semiconductor device according to claim 6, wherein
the peak of the concentration profile of the first impurity has a concentration of 5×10¹⁶ atoms/cm³ or higher and 1×10¹⁹ atoms/cm³ or lower, and
the peak of the concentration profile of the third impurity has a concentration of 1×10¹⁹ atoms/cm³ or higher.

8. The semiconductor device according to claim 1, wherein
the second region includes a peak of the concentration profile of the third impurity,
the first region and the second region each extend in a substrate planar direction, and
the concentration profile of the first impurity having the peak in the first region and the concentration profile of the third impurity having the peak in the second region are included in the first region near the semiconductor channel.

9. The semiconductor device according to claim 8, wherein
the concentration profile of the second impurity, which is higher in concentration than the concentration profile of the first impurity, is not included in the first region near the semiconductor channel and is included in the first region apart from the semiconductor channel.

10. The semiconductor device according to claim 1, wherein
the first impurity includes boron,
the second impurity includes arsenic, and
the third impurity includes carbon.

11. A semiconductor device comprising:
a first stacked body disposed above a substrate and in which a plurality of conductive films extending in a first direction are interspatially arranged in a layering direction;
a first separating member adjacent to, in a second direction intersecting the first direction, a first end of the first stacked body in the second direction, the first separating member extending in the first direction;
a second separating member adjacent to, in the second direction, a second end of the first stacked body in the second direction, the second separating member extending in the first direction;
a plurality of semiconductor channels each of which penetrates the first stacked body in the layering direction and couples to the substrate;
a first region disposed in the substrate and including a first peak of a concentration profile of a first impurity of a first conductivity type, the first region extending from a surface of the substrate, through a depth range including a concentration profile of a second impurity of a second conductivity type higher in concentration than the concentration profile of the first impurity having the first peak, to a depth of an intersection of the concentration profile of the first impurity having the first peak and the concentration profile of the second impurity; and
a second region disposed in the substrate and including a second peak of a concentration profile of a third impurity, the second region overlapping at least part of the first region in the layering direction, the concentration profile of the third impurity having the second peak being higher in concentration than the concentration profile of the first impurity through a depth direction of the second region, wherein
the first region and the second region each extend in a substrate planer direction, and
the second peak of the concentration profile of the third impurity in the second region which overlaps at least the part of the first region is formed within the substrate between the plurality of semiconductor channels in the substrate planer direction.

12. The semiconductor device according to claim 11, wherein
the first region and the second region are coupled to side surfaces of the plurality of semiconductor channels respectively.

13. The semiconductor device according to claim 11, wherein
the concentration profile of the second impurity is not included in the first region between the plurality of semiconductor channels in the substrate planar direction.

14. The semiconductor device according to claim 11, wherein
at least one of the first separating member and the second separating member has: an electrode member extending in the first direction and having a lower end reaching the first region; and an insulating member disposed between the electrode member and the plurality of conductive films, and
the concentration profile of the second impurity in the first region is locally included in the substrate planer direction including a substrate portion below the electrode member.

15. The semiconductor device according to claim 11, further comprising
a second stacked body disposed above the substrate and in which a plurality of conductive films extending in the first direction are interspatially arranged in the layering direction, wherein
one of the first separating member and the second separating member is disposed between the first stacked body and the second stacked body.

16. The semiconductor device according to claim 11, wherein
the second region overlaps the first region throughout a depth direction of the first region.

17. The semiconductor device according to claim 11, wherein
the second region overlaps the first region on a side of the surface of the substrate in a depth direction of the first region

18. The semiconductor device according to claim 11, wherein
the second region overlaps the first region on a side of the intersection in a depth direction of the first region.

19. The semiconductor device according to claim 11, wherein
the first impurity includes boron,
the second impurity includes arsenic, and
the third impurity includes carbon.

20. The semiconductor device according to claim 11, wherein
the plurality of semiconductor channels reach the first region and the second region.
